(19) United States
(12) Patent Application Publication
(10) Pub. No.: US 2023/0107554 A1
(43) Pub. Date: Apr. 6, 2023

(54) SEMICONDUCTOR PACKAGE AND MANUFACTURING METHOD THEREOF

(71) Applicant: KOREA ELECTRONICS TECHNOLOGY INSTITUTE, Seongnam-si (KR)

(72) Inventors: Jong Min YOOK, Seongnam-si (KR); Je In YU, Seoul (KR); Dong Su KIM, Seongnam-si (KR)

(21) Appl. No.: 17/899,891

(22) Filed: Aug. 31, 2022

(30) Foreign Application Priority Data
Sep. 30, 2021 (KR) 10-2021-0130313

(51) Int. Cl. H01L 23/13; H01L 23/367; H01L 23/00; H01L 21/48; H01L 23/15; H01L 23/66; H01L 23/498; H01L 21/56; H01L 23/31

(52) U.S. Cl. CPC H01L 23/13; H01L 21/486; H01L 21/565; H01L 21/4857; H01L 23/15; H01L 23/66; H01L 23/3107; H01L 23/3677; H01L 23/49816; H01L 23/49822; H01L 23/49838; H01L 24/11; H01L 24/16; H01L 2223/6622; H01L 2223/6677; H01L 2224/11849; H01L 2224/16227; H01L 2224/16238; H01L 2924/1421; H01L 2924/2027; H01L 2924/15151; H01L 2924/15153; H01L 2924/37001; H01Q 1/38

(57) ABSTRACT

A semiconductor package including a semiconductor chip, and a package structure configured to accommodate the semiconductor chip, and a manufacturing method thereof are disclosed. The package structure includes a substrate having one surface and the other surface opposite to the one surface, at least one conductive via extending through one surface and the other surface of the substrate, a wiring layer formed at one surface of the substrate, to transmit an electrical signal, a chip accommodating portion formed through removal of a portion of the substrate from the other surface toward the one surface, and a contact pad connected to the wiring layer and formed to be exposed through the chip accommodating portion. The semiconductor chip is inserted into the chip accommodating portion and is connected to the contact pad. Since the semiconductor chip is mounted after formation of the package structure, yield of the semiconductor package increases.

### CROSS REFERENCE TO RELATED APPLICATION

The present application claims priority to Korean Patent Application No. 10-2021-0130313, filed Sep. 30, 2021, the entire contents of which are incorporated herein for all purposes by this reference.

### BACKGROUND OF THE INVENTION

### Field of the Invention

The present invention relates to a semiconductor package and a manufacturing method thereof.

### Description of the Related Art

Recently, a high-frequency signal of a millimeter-wave band has been usable in accordance with advances in communication technology. Among semiconductor packages for communication, an antenna-in-package (AiP) is a structure in which an antenna is formed at a semiconductor package. Although the AiP, which is a structure in which a semiconductor chip is attached to a back surface of a package, is easy to manufacture, the height and size of a bump for mounting of a semiconductor chip are increased when the semiconductor chip has a great thickness and, as such, integration degrees of inputs and outputs at the back surface of the package are low. In the case of an AiP having a structure in which a semiconductor chip is accommodated in a package, and a redistribution layer or an antenna is formed on the semiconductor chip, it may be difficult to secure a desired yield in a multilayer forming procedure of forming the redistribution layer or the antenna after mounting of the semiconductor chip.

### PRIOR ART LITERATURE

### Patent Documents

Patent Document 1: KR 10-2020-0114084 A

### SUMMARY OF THE INVENTION

Therefore, the present invention has been made in view of the above problems, and it is an object of the present invention to provide a semiconductor package manufactured using a photosensitive glass substrate and configured in such a manner that, after complication of manufacture of a package structure including an antenna, a semiconductor chip is mounted on the package structure, to be coupled to the package structure, and a manufacturing method of the semiconductor package.

In accordance with an aspect of the present invention, the above and other objects can be accomplished by the provision of a semiconductor package including a semiconductor chip, and a package structure configured to accommodate the semiconductor chip therein.

The package structure may include a substrate having one surface and the other surface opposite to the one surface, at least one conductive via extending through the one surface and the other surface of the substrate, a wiring layer formed at the one surface of the substrate, to transmit an electrical signal, a chip accommodating portion as a space formed through removal of a portion of the substrate from the other surface in a direction toward the one surface, and a contact pad connected to the wiring layer and formed to be exposed through the chip accommodating portion.

The semiconductor chip may be inserted into the chip accommodating portion and may be connected to the contact pad.

The wiring layer may include a first insulating layer formed at the one surface of the substrate, to cover the contact pad exposed through the chip accommodating portion, a first electrode pattern layer formed on the first insulating layer, to electrically interconnect the contact pad and the conductive via, a second insulating layer formed on the first insulating layer, to cover the first electrode pattern layer, a second electrode pattern layer formed on the second insulating layer, to provide a ground, a third insulating layer formed on the second insulating layer, to cover the second electrode pattern layer, and a third electrode pattern layer formed on the third insulating layer, the third electrode pattern layer including an antenna.

The semiconductor package may further include a mold filled between the chip accommodating portion and the semiconductor chip and formed to cover the other surface of the substrate and the semiconductor chip, an input/output pad connected to the conductive via while extending through the mold, and a heat dissipation pad contacting an inactive surface of the semiconductor chip while extending through the mold.

The substrate may include a residual portion remaining after the substrate is removed to a predetermined depth from the other surface thereof in a direction toward the one surface thereof.

The contact pad is formed to be exposed through the chip accommodating portion while extending through the residual portion.

The semiconductor package may further include a first bump formed at the contact pad, and a portion of the first bump may protrude into an interior of the chip accommodating portion at the residual portion.

The contact pad may protrude toward the chip accommodating portion, thereby forming a protrusion.

In accordance with a further aspect of the present invention, there is provided a manufacturing method of a semiconductor package including a substrate machining step of forming at least one through hole at a substrate made of a photosensitive glass material such that the through hole extends through one surface and the other surface of the substrate, and forming, at the substrate, a denaturation region where a chip accommodating portion will be formed, a transmission path forming step of forming a conductive layer at the through hole, thereby forming a conductive via, forming a contact pad in the denaturation region, and forming a wiring layer for transmission of an electrical signal at the one surface of the substrate, an etching step of removing the denaturation region from the other surface of the substrate in a direction toward the one surface of the substrate, thereby forming the chip accommodating portion, and a mounting step of inserting a semiconductor chip into the chip accommodating portion, thereby connecting the semiconductor chip to the contact pad exposed through the chip accommodating portion.

The manufacturing method may further include a molding step of forming a mold such that the mold is filled between the chip accommodating portion and the semiconductor chip and covers the other surface of the substrate and the semiconductor chip, and an additional pad forming step of removing at least a portion of the mold, thereby not only forming an input/output pad connected to the conductive via while extending through the mold, but also forming a heat dissipation pad contacting an inactive surface of the semiconductor chip while extending through the mold.

The transmission path forming step may include a via forming step of forming the conductive layer at the through hole, thereby forming the conductive via, a contact pad forming step of forming the contact pad in the denaturation region, and a multilayer forming step of stacking a plurality of insulating layers and a plurality of electrode pattern layers at the one surface of the substrate, for transmission of an electrical signal.

The substrate machining step may include a through hole forming step of forming at least one through hole extending through the one surface and the other surface of the substrate, a groove forming step of forming at least one contact pad groove having a shape concave from the one surface of the substrate toward the other surface of the substrate at a portion of the substrate where the denaturation region will be formed, and a denaturation step of denaturing a portion of the substrate where the semiconductor chip will be mounted, thereby forming the denaturation region.

The contact pad forming step may include filling the contact pad groove formed in the denaturation region with a conductive material, thereby forming the contact pad.

The etching step may include etching the denaturation region from the other surface toward the one surface of the substrate, and stopping the etching when the contact pad is exposed, thereby forming a residual portion having a predetermined thickness from the one surface of the substrate toward the other surface of the substrate.

The multilayer forming step may include directly forming a second insulating layer at the one surface of the substrate such that the second insulating layer covers the contact pad, and sequentially forming a second electrode pattern layer, a third insulating layer and a third electrode pattern layer.

The manufacturing method may further include a protruded bump forming step between the via forming step and the contact pad forming step.

The protruded bump forming step may include exposing the contact pad groove, forming a mask such that the mask covers the one surface of the substrate, sequentially forming a seed layer, a solder and an under-bump metal along an inner wall of the contact pad groove, thereby forming a concave portion at a central portion of the under-bump meta, and removing the mask.

The contact pad forming step comprises filling the concave portion of the under-bump metal, thereby forming a contact pad having a protrusion protruding in a direction toward the other surface of the substrate.

The etching step may include etching the denaturation region from the other surface of the substrate toward the one surface of the substrate, and stopping the etching when the contact pad is exposed after exposure of the seed layer, thereby forming a residual portion having a predetermined thickness from the one surface of the substrate toward the other surface of the substrate.

The manufacturing method may further include, between the etching step and the mounting step, a reflow step of removing the seed layer, and performing reflow of the solder, thereby forming a first bump.

Prior to the description, it should be understood that the terms used in the specification and appended claims should not be construed as limited to general and dictionary meanings, but interpreted based on the meanings and concepts corresponding to technical aspects of the present invention on the basis of the principle that the inventor is allowed to define terms appropriately for best explanation.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a view showing a semiconductor package according to an exemplary embodiment of the present invention;

FIG. 2 is a flowchart showing a manufacturing method of a semiconductor package according to an exemplary embodiment of the present invention;

FIG. 3 is a view showing steps of the manufacturing method of the semiconductor package according to the exemplary embodiment of the present invention;

FIG. 4 is a view showing the semiconductor package, which exhibits enhanced heat dissipation in accordance with an exemplary embodiment of the present invention;

FIG. 5 is a view showing a semiconductor package having a residual portion according to an exemplary embodiment of the present invention;

FIG. 6 is a flowchart showing a manufacturing method of the semiconductor package having the residual portion according to an exemplary embodiment of the present invention;

FIGS. 7 and 8 are views showing steps of the manufacturing method of the semiconductor package having the residual portion according to the exemplary embodiment of the present invention;

FIG. 9 is a view showing a semiconductor package enhanced in heat dissipation while having a residual portion in accordance with an exemplary embodiment of the present invention;

FIG. 10 is a view showing a package structure of a semiconductor package having a protruded contact pad in accordance with an exemplary embodiment of the present invention;

FIG. 11 is a view showing a manufacturing method of the semiconductor package having the protruded contact pad according to an exemplary embodiment of the present invention; and

FIGS. 12 and 13 are views showing steps of the manufacturing method of the semiconductor package having the protruded contact pad according to the exemplary embodiment of the present invention.

### DETAILED DESCRIPTION OF THE INVENTION

Objects, particular advantages and new features of the present invention will be more clearly understood from the following detailed description and preferred embodiments taken in conjunction with the accompanying drawings. In the specification, in adding reference numerals for elements in each drawing, it should be noted that like reference numerals already used to denote like elements in other drawings are used for elements wherever possible. In addition, the terms “one surface”, “the other surface”, “first” and “second” are used to differentiate one constituent element from the other constituent element, and these constituent elements should not be limited by these terms. In the following description, when the detailed description of the relevant known function or configuration is determined to unnecessarily obscure the subject matter of the present invention, such detailed description will be omitted.

Meanwhile, it should be understood that terms representing directions such as upwards, downwards, left, right, an X-axis, a Y-axis, Z-axis, etc. are used in the specification, these terms are merely for convenience of description, and such directions may be expressed differently from those represented by the terms, in accordance with the viewing position of an observer or the position at which an object is disposed.

It should be noted that terms used herein are merely used to describe a specific embodiment, not to limit the present invention. Incidentally, unless clearly used otherwise, singular expressions include a plural meaning.

Hereinafter, exemplary embodiments of the present invention will be described in detail with reference to the accompanying drawings.

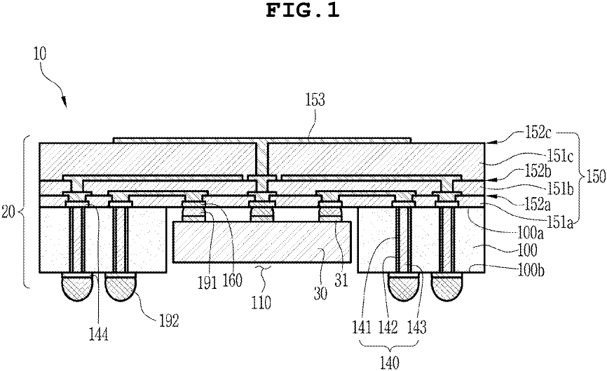

FIG. 1 is a view showing a semiconductor package 10 according to an exemplary embodiment of the present invention.

The semiconductor package 10 according to the exemplary embodiment of the present invention may include a semiconductor chip 30, and a package structure 20 configured to accommodate the semiconductor chip 30 therein. In this case, the package structure 20 may include a substrate 100 having one surface 100a and the other surface 100b opposite to the one surface 100a, at least one conductive via 140 extending through the one surface 100a and the other surface 100b of the substrate 100, a wiring layer 150 formed at the one surface 100a of the substrate 100, to transmit an electrical signal, a chip accommodating portion 110, which is a space formed through removal of a portion of the substrate 100 from the other surface 100b in a direction toward the one surface 100a, and a contact pad 160 connected to the wiring layer 150 and formed to be exposed through the chip accommodating portion 110. In addition, the semiconductor chip 30 may be inserted into the chip accommodating portion 110 and, as such, may be connected to the contact pad 160.

The semiconductor chip 30 may have an active surface and an inactive surface opposite to the active surface. A chip pad 31 may be formed at the active surface. The semiconductor chip 30 may operate in a high-frequency band of a millimeter wave or the like. The semiconductor chip 30 may include a chip for communication such as a radio-frequency integrated circuit (RFIC) or the like.

The package structure 20 includes a portion of the semiconductor package 10, except for the semiconductor chip 30. The package structure 20 may be referred to as an “interposer”. The package structure 20 may include the substrate 100, the wiring layer 150, the conductive via 140, the contact pad 160, etc. in order to package the semiconductor chip 30 and to transmit an electrical signal. In an embodiment of the present invention, the package structure 20 may be an independent product by itself. The package structure 20 may be commercially available as a finished product. The semiconductor package 10 may be manufactured by individually purchasing the semiconductor chip 30 and the package structure 20, and then mounting the semiconductor chip 30 on the package structure 20.

In an embodiment of the present invention, the semiconductor package 10 may be manufactured in the order of first manufacturing the package structure 20, in which an antenna 153, the wiring layer 150, bumps 191 and 192, etc. have been completely embodied, and then mounting the semiconductor chip 30 on the package structure 20. Once the package structure 20 is completed, it may be possible to independently check whether or not there is a defect in the package structure 20 itself. The semiconductor package 10 is manufactured by performing a process of mounting the semiconductor chip 30 on the package structure 20, which is normally operable, and, as such, a defect rate thereof is low.

The substrate 100 may be formed of a photosensitive glass material. When photosensitive glass is subjected to exposure, heating and etching, a structure having high precision may be manufactured. Accordingly, the conductive via 140 may be formed at a high integration degree, and the chip accommodating portion 110 may be precisely formed in accordance with the size and shape of the semiconductor chip 30. In addition, since photosensitive glass has a low coefficient of thermal expansion (CTE), a mounting process using the first bump 191 or the second bump 192 may be more precisely performed.

As described above, the substrate 100 may have the one surface 100a and the other surface 100b opposite to the one surface 100a. Preferably, the substrate 100 has a greater thickness than the semiconductor chip 30. When the semiconductor chip 30 is inserted into the chip accommodating portion 110 formed at the substrate 100, the thickness of the substrate 100 may be determined such that the inactive surface of the semiconductor chip 30 does not protrude beyond the other surface 100b of the substrate 100.

As described above, the chip accommodating portion 110 may be formed at the substrate 100. At least one chip accommodating portion 110 may be formed. The chip accommodating portion 110 is a space formed through removal of a portion of the substrate 100 from the other surface 100b in a direction toward the one surface 100a. The chip accommodating portion 110 may be formed to correspond to a size or shape of the semiconductor chip 30. The chip accommodating portion 110 may be a hole extending through the one surface 100a and the other surface 100b or a groove formed to be concave from the other surface 100b of the substrate 100 in the direction toward the one surface 100a.

The chip accommodating portion 110 may be formed in plural. Semiconductor chips 30 may be mounted in a plurality of chip accommodating portions 110, respectively. The plurality of chip accommodating portions 110 may be interconnected through the wiring layer 150. The package structure 20 may function to interconnect the semiconductor chips 30 mounted in the chip accommodating portions 110. The semiconductor chips 30 mounted in respective chip accommodating portions 110 may be of the same kind or different kinds. Although an AiP structure in which the antenna 153 is formed at the wiring layer 150 is shown in FIG. 1, the AiP structure may be formed in the form of a structure in which the antennal 153 is not formed. In the case of the package structure 20, which functions to interconnect a plurality of semiconductor chips 30, the antenna 153 may not be formed at the wiring layer 150.

The conductive via 140 may be formed at the substrate 100. At least one conductive via 140 may be formed. The conductive via 140 may extend through the one surface 100a and the other surface 100b of the substrate 100 and, as such, may transmit an electrical signal from the one surface 100a to the other surface 100b of the substrate 100. The conductive via 140 may include a through hole 141 extending through from the one surface 100a to the other surface 100b of the substrate 100, and a conductive layer 142 formed at an inner surface of the through hole 141. The conductive via 140 may further include a via pad 144 connected to one end of the through hole 141, another via pad 144 connected to the other end of the through hole 141, and a filling material 143 filled in the through hole 141. The filling material may fill the conductive layer 142 formed in the form of a layer along the inner surface of the through hole 141. The filling material 143 may be a material having an electrical insulation property. The via pad 144 may function to easily achieve connection between one of an electrode pattern layer 152 of the wiring layer 150, the second bump 192 and an input/output pad 182 and the conductive layer 142 of the conductive via 140.

The wiring layer 150 may be formed at the one surface 100a of the substrate 100. The wiring layer 150 may include a multilayer structure in which a plurality of electrode pattern layers 152 for transmission of an electrical signal and a plurality of insulating layers 151 are formed. The electrode pattern layer 152 means a layer at which a plurality of electrode patterns is formed. In FIG. 1, the wiring layer 150 according to the embodiment of the present invention is shown as including three insulating layers 151 and three electrode pattern layers 152. In detail, the wiring layer 150 may include a first insulating layer 151a formed at the one surface 100a of the substrate 100, to cover the contact pad 160 exposed through the chip accommodating portion 110, a first electrode pattern layer 152a formed on the first insulating layer 151a, to electrically interconnect the contact pad 160 and the conductive via 140, a second insulating layer 151b formed on the first insulating layer 151a, to cover the first electrode pattern layer 152a, a second electrode pattern layer 152b formed on the second insulating layer 151b, to provide a ground, a third insulating layer 151c formed on the second insulating layer 151b, to cover the second electrode pattern layer 152b, and a third electrode pattern layer 152c formed on the third insulating layer 151c and including the antenna 153.

Since the first insulating layer 151a is directly formed on the same plane as the one surface 100a of the substrate 100, and the first electrode pattern layer 152a is formed on the first insulating layer 151a, the first electrode pattern layer 152a is not exposed through the chip accommodating portion 110. When the first electrode pattern layer 152a is formed under a condition that the first insulating layer 151a is not present, the first electrode pattern layer 152a may be exposed through the chip accommodating portion 110. In this case, when the semiconductor chip 30 is mounted in the chip accommodating portion 110 using the first bump 191, the first bump 191 may be melted and, as such, may cause short circuit of the first electrode pattern layer 152a, thereby causing an increase in defect rate. Otherwise, when foreign matter penetrates into a space between the chip accommodating portion 110 and the semiconductor chip 30, there may be a problem in that the first electrode pattern layer 151a may be short-circuited. In accordance with the exemplary embodiment of the present invention, the first insulating layer 151a protects the first electrode pattern layer 152a and, as such, the defect rate caused by short circuit of the first electrode pattern layer 152a may be reduced.

The second insulating layer 151b may be formed on the first insulating layer 151a in order to cover the first electrode pattern layer 152a. The second insulating layer 151b may electrically insulate the first electrode pattern layer 152a and the second electrode pattern layer 152b from each other.

The second electrode pattern layer 152b may be formed to provide an electrical ground to the third electrode pattern layer 152c. The second electrode pattern layer 152b may be formed on the second insulating layer 151b while having a flat plate shape.

The third insulating layer 151c may be formed on the second insulating layer 151b in order to cover the second electrode pattern layer 152b. The third insulating layer 151c may electrically insulate the second electrode pattern layer 152b and the third electrode pattern layer 152c from each other.

The third electrode pattern layer 152c may be formed on the third insulating layer 151c. The third electrode pattern layer 152c may include the antenna 153. The antenna 153 may be a portion of the third electrode pattern layer 152c. The antenna 153 may be formed in the form of a pattern of various sizes and various kinds. The antenna 153 may radiate an electrical signal received from the semiconductor chip 30 into the air, or may receive a radio wave in the air and may then transmit the received radio wave to the semiconductor chip 30. A protective layer (not shown) covering the third electrode pattern layer 152c in order to protect the third electrode pattern layer 152c may be further formed on the third insulating layer 151c.

The electrode pattern layer 152 may be formed such that a portion thereof extends through the first insulating layer 151a, the second insulating layer 151b and the third insulating layer 151c. The portion of the electrode pattern layer 152 extending through the insulating layer 151 may interconnect the first electrode pattern layer 152a, the second electrode pattern layer 152b and the third electrode pattern layer 152c. As shown in FIG. 1, an electrode pattern, which is connected between the semiconductor chip 30 and the third electrode pattern layer 152c via the first electrode pattern layer 152a and the second electrode pattern layer 152b, may be formed to extend through the first insulating layer 151a, the second insulating layer 151b and the third insulating layer 151c.

Meanwhile, the wiring layer 150 may include a plurality of insulating layers and a plurality of electrode patterns in order to interconnect a plurality of semiconductor chips 30 respectively mounted in a plurality of chip accommodating portions 110. Structures of the insulating layers and the electrode patterns may be variously designed in accordance with kinds of the plurality of semiconductor chips 30, structures and positions of the chip accommodating portions 110, disposition of an input/output path, etc. The wiring layer 150 may be formed to have a structure not only including the antenna 153, but also including an insulating layer and an electrode pattern for interconnection of the semiconductor chips 30 mounted in the plurality of chip accommodating portions 110.

The second bump 192 may be formed at the via pad 144 formed at the other end of the conductive via 140. One end of the conductive via 140 may be disposed at the one surface 100a of the substrate 100, and the other end of the conductive via 140 may be disposed at the other surface 100b of the substrate 100. The second bump 192 may connect the semiconductor package 10 to an external circuit (not shown). It may be possible to minimize the size of the second bump 192 in accordance with a structure in which the semiconductor chip 30 is completely accommodated in the chip accommodating portion 110, that is, a structure in which the inactive surface of the semiconductor chip 30 does not protrude beyond the other surface 100b of the substrate 100.

When the semiconductor chip 30 protrudes downwards beyond the other surface 100b of the substrate 100, it is necessary to form the second bump 192 such that the second bump 192 has a size increased corresponding to a protruding height thereof. When the size of the second bump 192 is increased, signal transmission characteristics are degraded, and the integration degree of the input/output path is lowered, thereby causing the semiconductor package to have an increased size. On the other hand, in the exemplary embodiment of the present invention, the size of the second bump 192 is minimized and, as such, transmission characteristics of an electrical signal of a millimeter-wave band become excellent. The integration degree of the second bump 192 is also enhanced and, as such, the size of the semiconductor package may be reduced.

The contact pad 160 may be formed separately from the first electrode pattern layer 152a. The contact pad 160 may be formed at the same surface as the via pad 144 directly formed at the one surface 100a of the substrate 100. The contact pad 160 is exposed through the chip accommodating portion 110. The contact pad 160 may be formed at a position corresponding to that of the chip pad 31 while corresponding in number to the chip pad 31. An upper surface of the contact pad 160 may be connected to the first electrode pattern layer 152a. A lower surface of the contact pad 160 is exposed through the chip accommodating portion 110. The lower surface of the contact pad 160 may be connected to the chip pad 31 via the first bump 91.

Since the above-described semiconductor package 10 has a structure in which the semiconductor chip 30 is accommodated in the chip accommodating portion 110, the semiconductor package 10 may be easily mounted at a back side. In addition, since the active surface of the semiconductor chip 30 is coupled in a state of facing the wiring layer 150 of the semiconductor package 10, it may be possible to minimize a path for transmitting a high-frequency electrical signal output from the semiconductor chip 30 to the antenna 153 formed at the wiring layer 150. Since the path for transmitting a high-frequency electrical signal is minimized, an enhancement in efficiency and an enhancement in characteristics of wave transmission may be achieved.

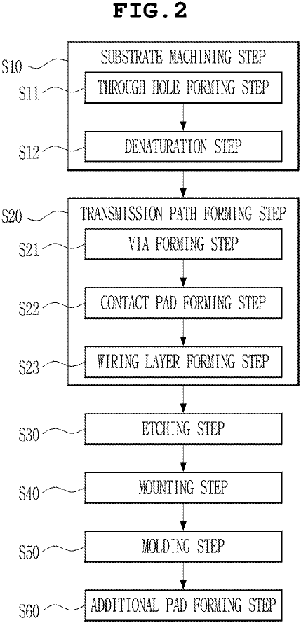

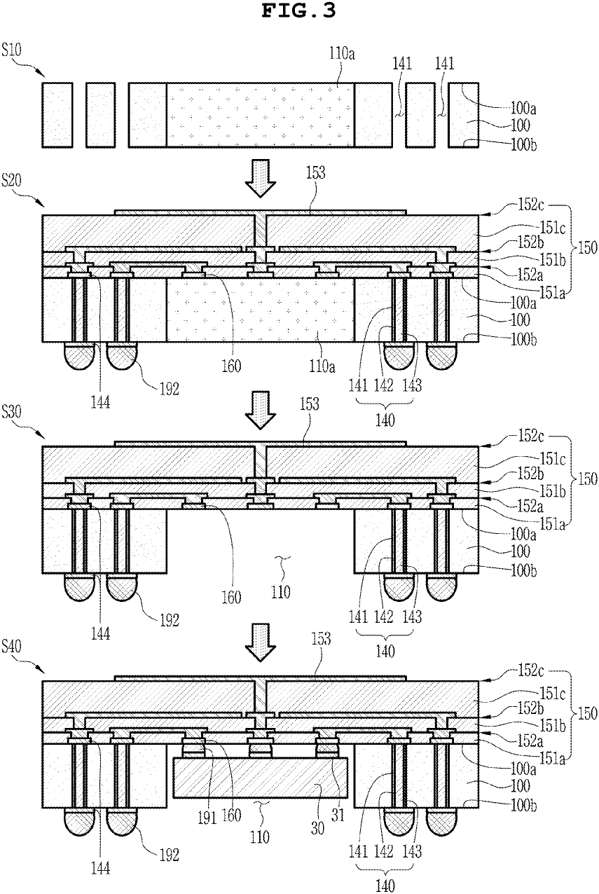

FIG. 2 is a flowchart showing a manufacturing method of a semiconductor package 10 according to an exemplary embodiment of the present invention. FIG. 3 is a view showing steps of the manufacturing method of the semiconductor package 10 according to the exemplary embodiment of the present invention. The following description will be given with reference to FIGS. 2 and 3.

The manufacturing method of the semiconductor package 10 according to the exemplary embodiment of the present invention may include a substrate machining step S10 of forming at least one through hole 141 at a substrate 100 made of a photosensitive glass material such that the through hole 141 extends through one surface 100a and the other surface 100b of the substrate 100, and forming, at the substrate 100, a denaturation region 110a where a chip accommodating portion 110 will be formed, a transmission path forming step S20 of forming a conductive layer 142 at the through hole 141, thereby forming a conductive via 140, forming a contact pad 160 in the denaturation region 110a, and forming a wiring layer 150 for transmission of an electrical signal at the one surface 100a of the substrate 100, an etching step S30 of removing the denaturation region 110a from the other surface 100b of the substrate 100 in a direction toward the one surface 100a of the substrate 100, thereby forming the chip accommodating portion 110, and a mounting step S40 of inserting a semiconductor chip 30 into the chip accommodating portion 110, thereby connecting the semiconductor chip 30 to the contact pad 160 exposed through the chip accommodating portion 110.

In accordance with an embodiment of the present invention, the mounting step S40 is performed after formation of a package structure 20 through execution of the substrate machining step S10, the transmission path forming step S20 and the etching step S30. In the case of a conventional semiconductor package 10, a process of forming a wiring layer 150 is performed after mounting of a semiconductor chip 30 on a substrate 100 and, as such, a defect may be generated at the semiconductor chip 30 during the wiring forming process. On the other hand, in the embodiment of the present invention, the semiconductor chip 30 is finally mounted and, as such, it may be possible to minimize a defect rate and to secure an excellent mass-production yield.

The substrate machining step S10 may include a through hole forming step S11 of forming at least one through hole 141 extending through the one surface 100a and the other surface 100b of the substrate 100, and a denaturation step S12 of denaturing a portion of the substrate 100 where the semiconductor chip 30 will be mounted, thereby forming the denaturation region 110a. In FIG. 3, “S10” represents a state in which the substrate machining step S10 has been performed.

The through hole forming step S11 is a procedure of forming the through hole 141 in order to form the conductive via 140 at the substrate 100 made of the photosensitive glass material. In the through hole forming step S11, the through hole 141 is formed by exposing, to ultraviolet light or the like, the portion of the substrate 100 where the conductive via 140 will be formed, performing heat treatment, thereby denaturing a portion of the substrate 100, and then performing etching, thereby removing the denatured portion of the substrate 100. In the specification, “denaturation” means a procedure of irradiating the substrate 100 made of the photosensitive glass material with ultraviolet light or the like, and heating the substrate 100, thereby crystallizing the substrate portion irradiated with the ultraviolet light. When the photosensitive glass substrate 100 is etched using hydrogen fluoride (HF), the denatured substrate portion is removed and, as such, the through hole 141 is formed at the substrate 100.

The denaturation step S12 is a procedure of forming the denaturation region 110a at a portion of the substrate 100. The denaturation region 110a is a portion of the substrate 100 where the chip accommodating portion 110 is to be formed. The chip accommodating portion 110 is formed to correspond to the size and shape of the semiconductor chip 30 and, as such, the denaturation region 110a may also be formed to correspond to the size and shape of the semiconductor chip 30. In the denaturation step S12, the portion of the substrate 100 is irradiated with ultraviolet light or the like, and is then heated, thereby denaturing the denaturation region 110a. As the denaturation step S12 is performed, the denaturation region 110a, which is a crystallized portion of the substrate 100, may be formed. The denaturation region 110a may be formed as a portion of the substrate 100 is crystallized. The denaturation region 110a is not in a state of having been removed from the substrate 100 and, as such, the wiring layer 150 may be formed on one surface of the denaturation region 110a.

The denatured and crystallized portion of the photosensitive glass substrate 100 exhibits a rapid etching rate, whereas an undenatured portion of the photosensitive glass substrate 100 exhibits a slow etching rate. Since the etching rate of the denatured portion of the substrate 100 is as rapid as about 40 times the etching rate of the undenatured portion of the substrate 100, the undenatured portion of the substrate 100 is hardly removed. Accordingly, a precise structure may be manufactured. The through hole 141 and the chip accommodating portion 110 may also be precisely fabricated.

After execution of the substrate machining step S10, the transmission path forming step S20 may be performed. In FIG. 3, “S20” represents a state in which the transmission path forming step S20 has been performed.

The transmission path forming step S20 may include a via forming step S21 of forming the conductive layer 142 at the through hole 141, thereby forming the conductive via 140, a contact pad forming step S22 of forming the contact pad 160 on the denaturation region 110a, and a wiring layer forming step S23 of stacking a plurality of insulating layers 151 and a plurality of electrode pattern layers 152 at the one surface 100a of the substrate 100, for transmission of an electrical signal. The transmission path includes a path, through which an electrical signal is transmitted, such as the conductive via 140, the contact pad 160, a via pad 144 and the wiring layer 150.

The via forming step S21 is a procedure of forming the conductive via 140. The conductive via 140 may be formed by forming the conductive layer 142 at an inner surface of the through hole 141 formed at the substrate 100 in the via forming step S21 such that the conductive layer 142 has a layer shape. After formation of the conductive layer 142, a filling material 143 may be further formed in a space defined inside the conductive layer 142. The filling material 143 may fill an interior of the conducive via 140, thereby reducing a defect rate generated during formation of the wiring layer 150. In the via forming step S21, the conductive layer 142 may completely fill the interior of the through hole 141 and, as such, the filling material 143 may not be formed. The conductive layer 142 may be formed of metal such as copper (Cu), aluminum (Al), silver (Ag) or the like, an alloy including metal, or a material such as a compound having electrical conductivity or the like.

The contact pad forming step S22 is a procedure of forming the contact pad 160, to which the semiconductor chip 30 will be connected, at the one surface 100a of the substrate 100. The contact pad 160 may be formed of a material having electrical conductivity, as in the conductive layer 142. The contact pad 160 may be formed on the denaturation region 110a of the substrate 100. Since the denaturation region 110a is a part of the substrate 100, and is not in a removed state, the contact pad 160 may be formed on the denaturation region 110a. The contact pad 160 may be formed through a method of patterning a metal layer. In the contact pad forming step S22, the via pad 144 may be formed at both ends of the conductive via 140. The contact pad 160 and the via pad 144 may be simultaneously formed using the same material. For example, the contact pad 160 and the via pad 144 may be simultaneously formed through execution of a procedure of performing plating and patterning at both surfaces of the substrate 100.

After execution of the contact pad forming step S22, the wiring layer forming step S23 may be performed.

The wiring layer forming step S23 is a procedure of forming at least one insulating layer 151 and at least one electrode pattern layer 152 through stacking. The wiring layer 150 may include a plurality of insulating layers 151 and a plurality of electrode pattern layers 152. The wiring layer forming step S23 may include forming a first insulating layer 151a covering the via pad 144 and the contact pad 160 formed on the one surface 100a of the substrate 100, forming, on the first insulating layer 151a, a first electrode pattern layer 152a connected to the via pad 144 or the contact pad 160, for transmission of an electrical signal, forming a second insulating layer 151b on the first insulating layer 151a, to cover the first electrode pattern layer 152a, forming a second electrode pattern layer 152b on the second insulating layer 151b such that the second electrode pattern layer 152b is connected to a portion of the first electrode pattern layer 152a, forming a third insulating layer 151c on the second insulating layer 151b, to cover the second electrode pattern layer 152b, and forming a third electrode pattern layer 152c on the third insulating layer 151c such that the third electrode pattern layer 152c is connected to a portion of the second electrode pattern layer 152b. The insulating layer 151 may be formed of various kinds of materials having electrical conductivity. In the wiring layer forming step S23, a second bump 192 may be formed at the via pad 144 formed at the other surface of the conductive via 140. The second bump 192 may be formed before or after mounting of the semiconductor chip 30.

After execution of the transmission path forming step S20, the etching step S30 may be performed. In FIG. 3, “S30” represents a state in which the etching step S30 has been performed.

The etching step S30 is a procedure of removing the denaturation region 110a formed at the substrate 100. In the etching step S30, the denatured portion of the substrate 100 is removed using an acid solution such as hydrogen fluoride (HF) or the like. In accordance with removal of the denaturation region 110a, the chip accommodating portion 110 is formed at the substrate 100. The etching proceeds in a direction from the other surface 100b to the one surface 100a of the substrate 100, and is stopped when the contact pad 160 formed at the one surface 100a of the substrate 100 is exposed.

When the method is performed up to the etching step S30, the package structure 20, which may accommodate the semiconductor chip 30, is completed. In a state in which the package structure 20 is completed, whether or not there is a defect in the package structure 20 itself may be checked.

After execution of the etching step S30, the mounting step S40 may be performed. In FIG. 3, “S40” represents a state in which the mounting step S40 has been performed.

The mounting step S40 is a procedure of mounting the semiconductor chip 30 in the chip accommodating portion 110 of the package structure 20. The semiconductor chip 30 is mounted such that the chip pad 31 faces the wiring layer 150, and is connected to the contact pad 160 via the first bump 191. After mounting of the semiconductor chip 30, manufacture of the semiconductor package 10 is completed.

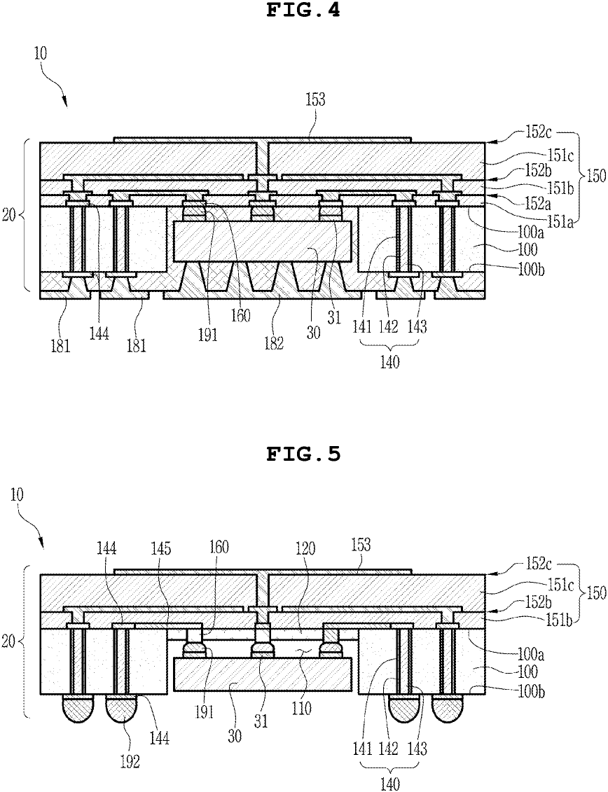

FIG. 4 is a view showing the semiconductor package 10, which exhibits enhanced heat dissipation in accordance with an exemplary embodiment of the present invention.

As shown in FIG. 4, the semiconductor packager 10 according to the exemplary embodiment of the present invention may further include a mold 170 filled between the chip accommodating portion 110 and the semiconductor chip 30 and formed to cover the other surface 100b of the substrate 100 and the semiconductor chip 30, an input/output pad 182 connected to the conductive via 140 while extending through the mold 170, and a heat dissipation pad 181 contacting the inactive surface of the semiconductor chip 30 while extending through the mold 170.

The mold 170, the input/output pad 182 and the heat dissipation pad 181 are additional configurations which may be formed after completion of the semiconductor package 10. The mold 170 may be formed of a molding compound having an electrical insulation property. The mold 170 fills a space between the semiconductor chip 30 and the chip accommodating portion 110 and, as such, may fix the semiconductor chip 30 and the package structure 20. The mold 170 may not only cover the inactive surface of the semiconductor chip 30, but also may cover the other surface 100b of the substrate 100. The input/output pad 182 may be connected to the via pad 144 of the conductive via 140 and, as such, may transmit an electrical signal. The input/output pad 182 may be connected to the via pad 144 while extending through the mold 170. The input/output pad 182 may be connected to an external circuit board (not shown). The heat dissipation pad 181 may contact the inactive surface of the semiconductor chip 30 and, as such, may outwardly dissipate heat generated by the semiconductor chip 30. The heat dissipation pad 181 may be formed to extend through the mold 170. The heat dissipation pad 181 may be connected to a heat sink of the external circuit board.

The manufacturing method of the semiconductor package 10 according to the exemplary embodiment of the present invention may further include a molding step S50 of forming the mold 170 such that the mold 170 is filled between the chip accommodating portion 110 and the semiconductor chip 30 and covers the other surface 100b of the substrate 100 and the semiconductor chip 30, and an additional pad forming step S60 of removing at least a portion of the mold 170, thereby not only forming the input/output pad 182 connected to the conductive via 140 while extending through the mold 170, but also forming the heat dissipation pad 181 contacting the inactive surface of the semiconductor chip 30 while extending through the mold 170. The molding step S50 and the additional pad forming step S60 are steps executed after mounting of the semiconductor chip 30 and may be selectively performed. When the heat dissipation pad 181 is formed through execution of the molding step S50 and the additional pad forming step S60, it may be possible to manufacture the semiconductor package 10 enhanced in heat dissipation performance of the semiconductor chip 30 thereof. When the procedure of forming the mold 170, the input/output pad 182 and the heat dissipation pad 181 is executed, the second bump 192 may not be formed in the transmission path forming step S20.

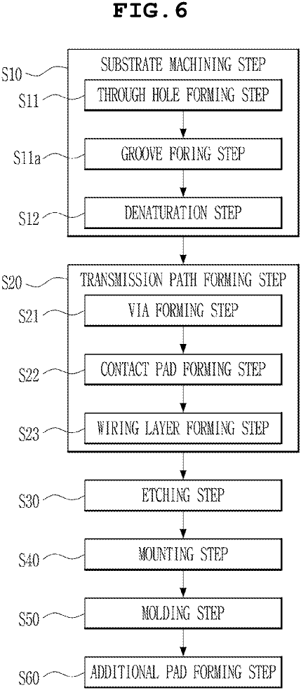

FIG. 5 is a view showing a semiconductor package 10 having a residual portion 120 according to an exemplary embodiment of the present invention. Hereinafter, the embodiment shown in FIG. 5 compared to that of FIG. 1 will be described.

The semiconductor package 10 shown in FIG. 5 is different from the semiconductor package 10 shown in FIG. 1 in that, in the semiconductor package 10 shown in FIG. 1, the contact pad 160 is formed on the same plane as the one surface 100a of the substrate 100 whereas, in the semiconductor package 10 shown in FIG. 5, a contact pad 160 is formed to be inserted into the substrate 100 in a direction from the one surface 100a to the other surface 100b of the substrate 100. In addition, the semiconductor package 10 of FIG. 5 is different from the semiconductor package 10 of FIG. 1 in that, in the semiconductor package 10 of FIG. 1, the chip accommodating portion 110 is formed in the form of a hole extending through the one surface 100a and the other surface 100b of the substrate 10 whereas, in the semiconductor package 10 of FIG. 5, a chip accommodating portion 110 is formed in the form of a groove concave from the other surface 100b in a direction toward the one surface 100a of the substrate 100. That is, the semiconductor package 10 shown in FIG. 5 has a structure in which the residual portion 120 is formed as a portion of the substrate 100 disposed at a side of the one surface 100a of the substrate 100 remains without being removed in the etching step S30 of forming the chip accommodating portion 110. Of course, the contact pad 160 is formed to extend through the substrate 100 such that the contact pad 160 is exposed at the one surface 100a of the substrate 100 through the chip accommodating portion 110, and the contact pad 160 is also connected to the chip pad 31 via a first bump 191. Descriptions overlapping with those of the semiconductor package 10 shown in FIG. 1 will be omitted.

In the semiconductor package 10 having the residual portion 120, the substrate 100 may include the residual portion 120 remaining after the substrate 100 is removed to a predetermined depth from the other surface 100b thereof in a direction toward the one surface 100a thereof. In this case, the contact pad 160 may be formed to be exposed through the chip accommodating portion 110 while extending through the residual portion 120. The residual portion 120 is a part of the substrate 100 and is formed to have a predetermined thickness from the one surface 100a of the substrate 100 in a direction toward the other surface 100b of the substrate 100. The residual portion 120 is a portion of the denaturation region 110a remaining after the denaturation region 110a is incompletely etched. The contact pad 160 is formed to extend through one surface of the residual portion 120 (that is, the one surface 100a of the substrate 100) and the other surface of the residual portion 120.

An upper end of the contact pad 160 may be connected to a connection portion 145 formed at the one surface of the residual portion 120 between the substrate 100 and the contact pad 160. A lower end of the contact pad 160 may be exposed through the chip accommodating portion 110 while extending through the residual portion 120. The connection portion 145 may be connected to the via pad 144. The connection portion 145 may be formed at the one surface of the residual portion 120 between the substrate 100 and the contact pad 160 and, as such, may interconnect the contact pad 160 and the via pad 144. It may be understood that connection to the via pad 144 in the specification means electrical connection to the conductive via 140. Since the connection portion 145 is formed at the one surface of the residual portion 120 and, as such, is not exposed through the chip accommodating portion 110, the first insulating layer 151a as shown in FIG. 1 may not be formed. In addition, the connection portion 145 may perform the same function as the first electrode pattern layer 152a as shown in FIG. 1 and, as such, the first electrode pattern layer 152a may also not be formed.

In the semiconductor package 10 having the residual portion 120, the first insulating layer 151a and the first pattern layer 152a of the wiring layer 150 may be omitted and, as such, the manufacturing process may be simplified. The wiring layer 150 may include a second insulating layer 151b formed at the one surface 100a of the substrate 100, to cover the via pad 144, the connection portion 145 and the contact pad 160, a second electrode pattern layer 152b formed to be connected to the via pad 144, the connection portion 145 or the contact pad 160 while extending through the second insulating layer 151b, a third insulating layer 151c formed on the second insulating layer 151b, to cover the second electrode pattern layer 152b, and a third electrode pattern layer 152c formed on the third insulating layer 151c, to be connected to a portion of the second electrode pattern layer 152b.

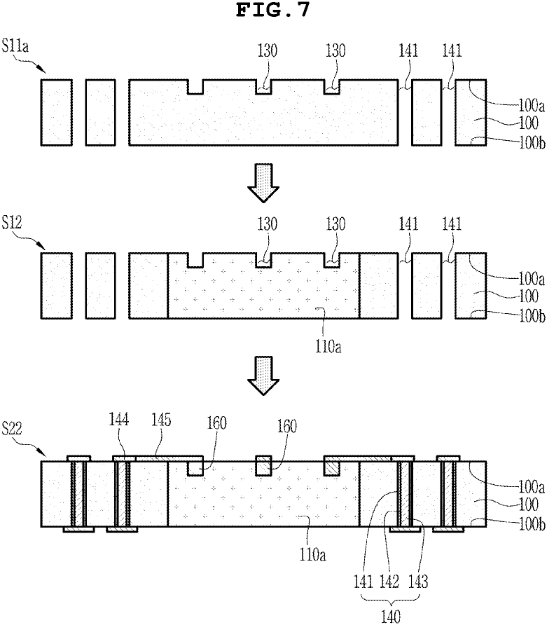

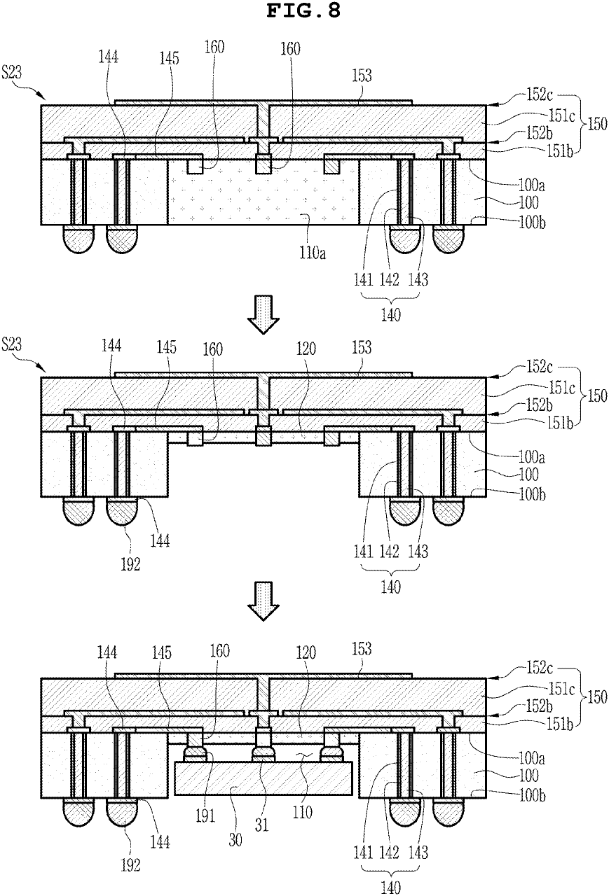

FIG. 6 is a flowchart showing a manufacturing method of the semiconductor package 10 having the residual portion 120 according to an exemplary embodiment of the present invention. FIGS. 7 and 8 are views showing steps of the manufacturing method of the semiconductor package 10 having the residual portion 120 according to the exemplary embodiment of the present invention.

In the manufacturing method shown in FIG. 6, a substrate machining step S10 is first performed. The substrate machining step S10 may include a through hole forming step S11 of forming at least one through hole 141 extending through one surface 100a and the other surface 100b of a substrate 100, a groove forming step S11a of forming at least one contact pad groove 130 having a shape concave from the one surface 100a of the substrate 100 in a direction toward the other surface 100b of the substrate 100, and a denaturation step S12 of denaturing a portion of the substrate 100 where a semiconductor chip 30 will be mounted, thereby forming a denaturation region 110a.

The through hole forming step S11 and the denaturation step S12 are identical to those described with reference to FIGS. 2 and 3 and, as such, no description thereof will be given. The groove forming step S11a may be performed between the through hole forming step S11 and the denaturation step S12. Alternatively, the groove forming step S11a may be performed simultaneously with the through hole forming step S11.

In FIG. 7, “S11a” represents a state in which the groove forming step S11a has been performed. The groove forming step S11a is a procedure of forming a contact pad groove 130 at the one surface 100a of the substrate 100 at a position where a contact pad 160 will be formed. The contact pad groove 130 may be formed at a portion of the one surface 100a of the substrate 100 where the denaturation region 110a will be formed. The contact pad groove 130 may be formed using a method of exposing, heating and etching a portion of the one surface 100a of the photosensitive glass substrate 100. The contact pad groove 130 may also be formed using a laser or a mechanical method.

In FIG. 7, “S12” represents a state in which the denaturation step S12 has been performed. After execution of the groove forming step S11a, the denaturation step S12 is performed and, as such, a region including the portion of the substrate 100 formed with the contact pad groove 130 is denatured, thereby forming the denaturation region 110a. The contact pad groove 130 is formed at one surface of the denaturation region 110a.

In FIG. 7, “S22” represents a state in which a contact pad forming step S22 has been performed. After execution of the denaturation step S12, a transmission path forming step S20 is performed. In the transmission path forming step 20, a via forming step S21 of forming a conductive via 140 is first performed, and the contact pad forming step S22 is then performed. In the contact pad forming step S22, a conductive material fills the contact pad groove 130 formed in the denaturation region 110a, thereby forming a contact pad 160. Simultaneously with formation of the contact pad 160, a via pad 144 may be formed, and a connection portion 145 interconnecting the via pad 145 and the contact pad 160 may be formed. The via pad 144, the contact pad 160 and the connection portion 145 may be directly formed on the one surface 100a of the substrate 100 using a double-sided wiring process. Since a residual portion 120 is present, the connection portion 145 interconnecting the via pad 144 and the contact pad 160 may be directly formed on the one surface 100a of the substrate 100 in the contact pad forming step S22.

In FIG. 8, “S23” represents a state in which a wiring layer forming step S23 has been performed. After execution of the contact pad forming step S22, the wiring layer forming step S23 is performed. In the wiring layer forming step S23, a second insulating layer 151b is directly formed at the one surface 100a of the substrate 100, to cover the contact pad 160, and a second electrode pattern layer 152b, a third insulating layer 151c and a third electrode pattern layer 152c may then be sequentially formed. The second insulating layer 151b may be directly formed at the one surface 100a of the substrate 100, to cover the via pad 144, the contact pad 160 and the connection portion 145. The reason why the second insulating layer 151b can be directly formed at the one surface 100a of the substrate 100 in the wiring layer forming step S23 under the condition that a first insulating layer 151a and a first electrode pattern 152a are omitted is that a residual portion 120 will be formed in an etching step S30. The residual portion 120 covers the connection portion 145 such that the connection portion 145 is not exposed through the chip accommodating portion 110, the first insulating layer 151a as shown in FIG. 1 may be omitted. In addition, since the residual portion 120 is present, the connection portion 145 may be formed in the contact pad forming step S22. The connection portion 145 may also perform substantially the same function as the first electrode pattern layer 152a and, as such, the first electrode pattern layer 152a may be omitted.

In FIG. 8, “S30” represents a state in which the etching step S30 has been performed. After execution of the wiring layer forming step S23, the etching step S30 may be performed. In the etching step S30, the denaturation region 110a is etched from the other surface 100b of the substrate 100 in a direction toward the one surface 100a of the substrate 100, and the etching is stopped when the contact pad 160 is exposed and, as such, the residual portion 120, which extends from the one surface 100a of the substrate 100 in a direction toward the other surface 100b of the substrate 100 by a predetermined thickness, may be formed. It may be possible to adjust the depth of the substrate 100 removed by etching by adjusting a time taken to etch the substrate 100 in the etching step S30. When a predetermined time elapses or the contact pad 160 is exposed after etching of the denaturation region 110a from the other surface 100b of the substrate 100 in a direction toward the one surface 100a of the substrate 100 is begun, the etching may be stopped. A portion of the denaturation area 110a remaining in accordance with incomplete etching of the denaturation area 110a is the residual portion 120.

In FIG. 8, “S40” represents a state in which a mounting step S40 has been performed. Execution of the mounting step S40 after the etching step S30 has been described with reference to FIG. 3 and, as such, no description thereof will be given.

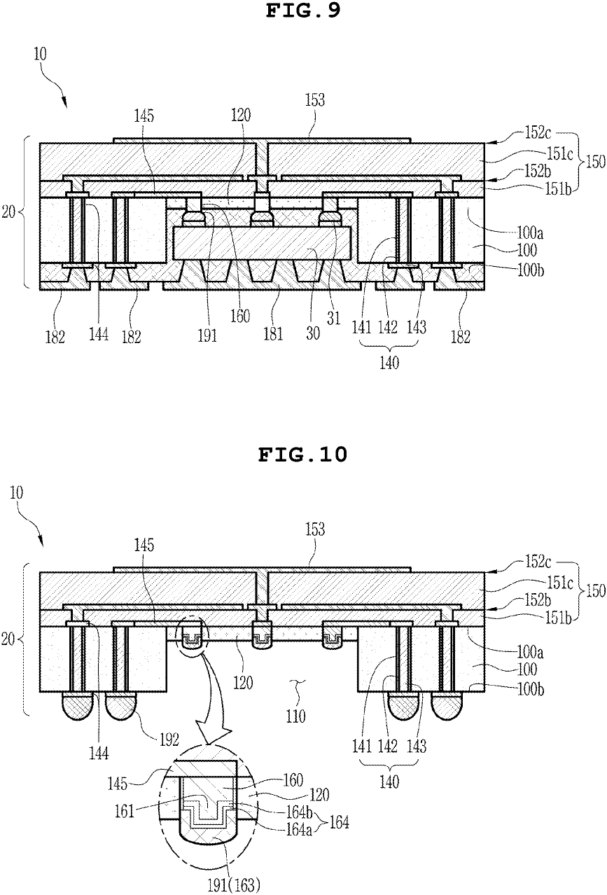

FIG. 9 is a view showing a semiconductor package 10 enhanced in heat dissipation while having a residual portion 120 in accordance with an exemplary embodiment of the present invention.

In the case of the semiconductor package 10 having the residual portion 120, a mold 170, a connection pad and a heat dissipation pad 181 may be further formed. Not only structures of the mold 170, the connection pad and the heat dissipation pad 181, but also a mold forming step S50 and an additional pad forming step S60, may be identical to those described with reference to FIG. 4 and, as such, no description thereof will be given.

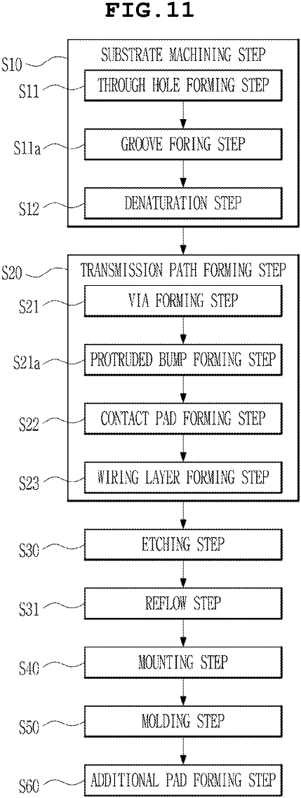

FIG. 10 is a view showing a package structure 20 of a semiconductor package 10 having a protruded contact pad 160 in accordance with an exemplary embodiment of the present invention. Description of configurations of the package structure 20 identical to those of the semiconductor packages 10 shown in FIGS. 1 and 5 will be omitted.

Identically to the semiconductor package 10 having the residual portion 120 as shown in FIG. 5, the semiconductor package 10 having the protruded contact pad 160 as shown in FIG. 9 has the residual portion 120. In the case of the semiconductor package 10, in which the contact pad 160 protrudes, as shown in FIG. 9, a protrusion 161 may be formed at the contact pad 160, an under-bump metal 164 may be formed at the protrusion 161, a first bump 191 may be formed at the under-bump metal 164, and the first bump 191 may be formed to protrude into an interior of a chip accommodating portion 110.

In the semiconductor package 10 according to the exemplary embodiment of the present invention, the contact pad 160 may be formed with the protrusion 161, a portion of which protrudes toward the chip accommodating portion 110. The protrusion 161 may be formed at a lower end of the contact pad 160, to protrude in a direction toward the other surface 100b of a substrate 100. The protrusion 161 may be formed such that a tip thereof protrudes below the other surface of the residual portion 120. The protrusion 161 may be connected to a chip pad 31 of a semiconductor chip 30 via the first bump 191. The under-bump metal 164 may be formed at the protrusion 161. The under-bump metal 164 may be formed in the form of two or more layers.

In the semiconductor package 10 according to the exemplary embodiment of the present invention, the first bump 191 may be further formed at the contact pad 160 such that a portion thereof protrudes from the residual portion 120 into the interior of the chip accommodating portion 110. The first bump 191 may be formed to surround the protrusion 161 of the contact pad 160. The first bump 191 may be formed of a solder or the like. The solder may be formed of a material such as Sn, SnAg or the like. The first bump 191 may be formed such that a central portion thereof is convex inwardly of the chip accommodating portion 110 in accordance with a protruding shape of the protrusion 161. The first bump 191 may be connected to the contact pad 160 at an edge thereof while being formed to be convex at the central portion thereof by the protrusion 161.

After the package structure 20 is completed as the protrusion 161 is formed at the contact pad 160, to protrude into the chip accommodating portion 110, and the first bump 191 is formed to be convex such that the first bump 191 surrounds the protrusion 161, the semiconductor chip 30 may be mounted in the chip accommodating portion 110. Since the semiconductor chip 30 is inserted into the chip accommodating portion 110 in a state in which the first bump 191 is connected to the contact pad 160, it may be possible to minimize a defect rate caused by separation of the first bump 191, etc. occurring in a reflow procedure for mounting of the semiconductor chip 30. The protrusion 161 formed at the contact pad 160 may further enhance electrical contact performance in a procedure of connecting the contact pad 160 to the chip pad 31.

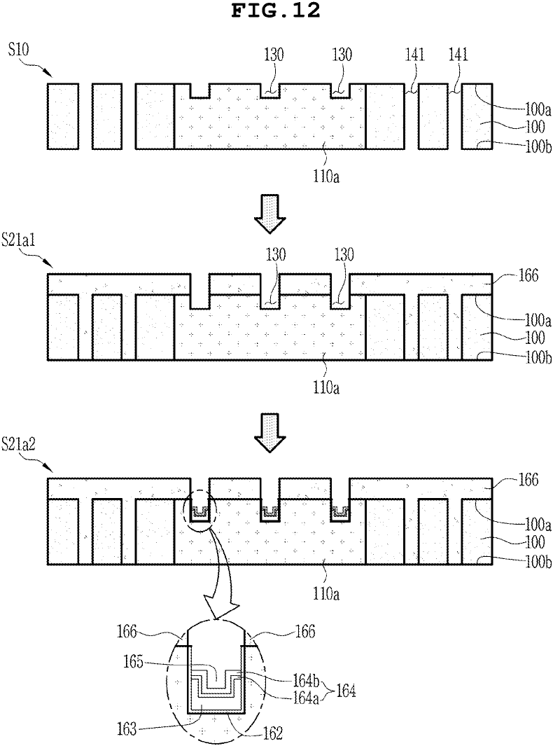

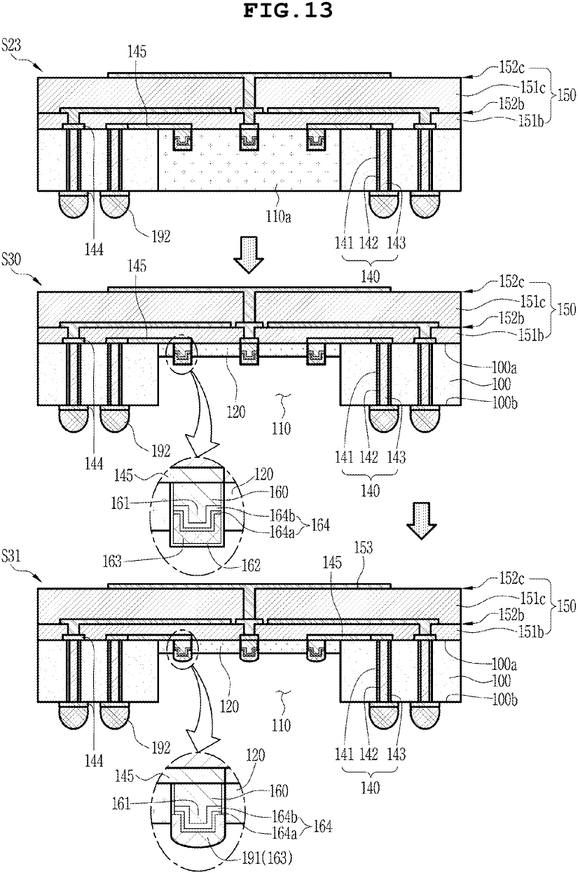

FIG. 11 is a view showing a manufacturing method of the semiconductor package 10 having the protruded contact pad 160 according to an exemplary embodiment of the present invention. FIGS. 12 and 13 are views showing steps of the manufacturing method of the semiconductor package 10 having the protruded contact pad 160 according to the exemplary embodiment of the present invention. Contents of this method identical to those of the method described with reference to FIGS. 6, 7 and 8 will be omitted.

The manufacturing method of the semiconductor package 10 according to the exemplary embodiment of the disclosure may further include a protruded bump forming step S21a between a via forming step S21 and a contact pad forming step S22. In the protruded bump forming step S21a, a contact pad groove 130 may be exposed, a mask 166 may then be formed to cover one surface 100a of a substrate 100, a seed layer 162, a solder 163 and an under-bump metal 164 may then be sequentially formed along an inner wall of the contact pad groove 130, thereby forming a concave portion 165 at a central portion of the under-bump metal 164, and the mask 166 may then be removed.

The protruded bump forming step S21a is a procedure of sequentially forming the seed layer 162, the solder 163 and the under-bump metal 164 at the contact pad groove 130. The protruded bump forming step S21a is a procedure of performing a process for forming a first bump 191 before formation of the contact pad 160 at the contact pad groove 130.

In FIG. 12, “S10” represents a state in which a substrate machining step S10 has been performed. In this state, a through hole 141, the contact pad groove 130 and a denaturation region 110a have been formed at the substrate 100.

In FIG. 12, “S21a1” represents a state in which the mask 166 has been first formed in the protruded bump forming step S21a. The mask 166 may be formed of photoresist or the like. A region exposed by the mask 166 is the contact pad groove 130.

In FIG. 12, “S21a2” represents a state in which the seed layer 162, the solder 163 and the under-bump metal 164 have been sequentially formed in the protruded bump forming step S21a. The seed layer 162 is first formed at the contact pad groove 130. The seed layer 162 may be formed of a material exhibiting high wettability with respect to the solder 163. The solder 163 may be formed along the seed layer 162 such that the solder 163 may closely contact a groove wall of the contact pad groove 130 in accordance with a shape of the contact pad groove 130 and, as such, a space may be present at a central portion of the solder 163. The under-bump metal 164 is formed on the solder 163. The under-bump metal 164 is formed in the form of a thin layer and, as such, may be formed such that a space is present at a central portion thereof, similarly to the solder 163. That is, the under-bump metal 164 may include a concave portion 165 formed to be concave in a direction toward the other surface 100b of the substrate 100. The solder 163 may be formed of a material such as Sn, SnAg, or the like. The first under-bump metal 164a is formed on the solder 163, and may be formed of a material such as Ni or the like. The second under-bump metal 164b is formed on the first under-bump metal 164a, and may be formed of a material such as Ag or the like. After formation of the under-bump metal 164, the mask 166 may be removed.

In FIG. 13, “S23” represents a state in which the contact pad forming step S22 has been performed, and a wiring layer forming step S23 has been performed. After formation of the under-bump metal 164, in the contact pad forming step S22, an electrically-conductive material fills the concave portion 165 of the under-bump metal 164, thereby forming the contact pad 160, which has a protrusion 161 protruding in a direction toward the other surface 100b of the substrate 100. When the contact pad 160 is formed by filling the concave portion 165 of the under-bump metal 164 with an electrically-conductive material in the contact pad forming step S22, the electrically-conductive material filling the concave portion 165 may form the protrusion 161 protruding in the direction toward the other surface 100b of the substrate 100. After execution of the contact pad forming step S22, the wiring layer forming step S23 may be performed.

In FIG. 13. “S30” represents a state in which an etching step S30 has been performed. In the etching step S30, the denaturation region 110a is etched from the other surface 100b of the substrate 100 in a direction toward the one surface 100a of the substrate 100, and the etching is stopped when the contact pad 160 is exposed after exposure of the seed layer 162 and, as such, a residual portion 120, which extends from the one surface 100a of the substrate 100 in a direction toward the other surface 100b of the substrate 100 by a predetermined thickness, may be formed.

When a predetermined time elapses or the other surface of the residual portion 120 becomes higher than a lower surface of the seed layer 162, a lower surface of the protrusion 161 or a lower surface of the contact pad 160 after etching of the denaturation region 110a from the other surface 100b of the substrate 100 in a direction toward the one surface 100a of the substrate 100 is begun in the etching step S30, the etching may be stopped. The residual portion 120 may be formed such that the other surface thereof is disposed nearer to the one surface 100a of the substrate 100 than the lower surface of the protrusion 161. It may be possible to manufacture a structure meeting characteristics of a semiconductor chip 30 by adjusting a relative position between the other surface of the residual portion 120 and each of the seed layer 162, the protrusion 161 and the contact pad 160.

In FIG. 13, “S31” represents a state in which a reflow step S31 has been performed. In accordance with an embodiment of the present invention, the manufacturing method of the semiconductor package 10 may further include, between the etching step S30 and a mounting step S40, the reflow step S31 in which a seed layer 162 is removed, and reflow of the solder 163 is performed, thereby forming a first bump 191. The reflow step S31 is a procedure of re-heating the solder 163 formed in accordance with a shape of the contact pad 160, thereby making the solder 163 have a shape in which the solder 163 is convex at a central portion thereof while contacting the contact pad 160 at an edge thereof. The seed layer 162 is formed to conform to an inner surface shape of the contact pad groove 130 and, as such, interferes with re-shaping of the solder 163 due to surface tension of the solder 163 in a reflow procedure. Accordingly, the seed layer 162 is first removed, and a reflow procedure is then performed by heating the solder 163. When the reflow step S31 is performed, a layer of the under-bump metal 164 may be formed at the protrusion 161 of the contact pad 160, and the first bump 191, which is constituted by the solder 163, may be formed at the layer of the under-bump metal 164.

In the manufacturing method of the semiconductor package 10 described with reference to FIGS. 2, 3, 6 and 7, connection of the first bump 191 to the contact pad 160 is achieved by coupling the first bump 191 to the contact pad 160 in a state of extending through the chip accommodating portion 110. On the other hand, in the manufacturing method of the semiconductor package 10 described with reference to FIGS. 10 and 11, the contact pad 160 is formed after formation of the solder 163 at the contact pad groove 130 and, as such, formation of the first bump 191 is achieved under the condition that the first bump 191 does not pass through the chip accommodating portion 110 and is not formed at the contact pad 160. Accordingly, it may be possible to remove possibility of generation of a defect such as short circuit or the like in a procedure of forming the first bump 191 at the contact pad 160 under the condition that the first bump 191 passes through the chip accommodating portion 110.

When the reflow step S31 is performed, the package structure 20 is completed. After execution of the reflow step S31, the mounting step S40 may be performed. Since the first bump 191 has already been formed at the package structure 20, the procedure of mounting the semiconductor chip 30 may be further simplified. The mounting step S40 of mounting the semiconductor chip 30 is omitted from FIG. 13.

A molding step S50 and an additional pad forming step S60 may be further performed in a state shown by “S31” in FIG. 13. The molding step S50 and the additional pad forming step S60 have been described with reference to FIG. 4 and, as such, no description thereof will be given.

As apparent from the above description, in accordance with the exemplary embodiments of the present invention, it may be possible to precisely manufacture a package structure for mounting of a semiconductor chip because a photosensitive glass substrate is used, and to minimize a defect rate because the semiconductor chip is coupled to the package structure after completion of the package structure.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A semiconductor package comprising:
a semiconductor chip; and
a package structure configured to accommodate the semiconductor chip therein,
wherein the package structure comprises:
a substrate having one surface and the other surface opposite to the one surface;
at least one conductive via extending through the one surface and the other surface of the substrate;
a wiring layer formed at the one surface of the substrate, to transmit an electrical signal;
a chip accommodating portion as a space formed through removal of a portion of the substrate from the other surface in a direction toward the one surface; and
a contact pad connected to the wiring layer and formed to be exposed through the chip accommodating portion, and
wherein the semiconductor chip is inserted into the chip accommodating portion and is connected to the contact pad.

2. The semiconductor package according to claim 1, wherein:
the substrate comprises a residual portion remaining after the substrate is removed to a predetermined depth from the other surface thereof in a direction toward the one surface thereof; and
the contact is formed to be exposed through the chip accommodating portion while extending through the residual portion.

3. The semiconductor package according to claim 2, further comprising:
a first bump formed at the contact pad, a portion of the first bump protruding into an interior of the chip accommodating portion at the residual portion.

4. The semiconductor package according to claim 3, wherein the contact pad protrudes toward the chip accommodating portion, thereby forming a protrusion.

5. The semiconductor package according to claim 1, further comprising:
a mold filled between the chip accommodating portion and the semiconductor chip and formed to cover the other surface of the substrate and the semiconductor chip;
an input/output pad connected to the conductive via while extending through the mold; and
a heat dissipation pad contacting an inactive surface of the semiconductor chip while extending through the mold.

6. The semiconductor package according to claim 1, wherein the wiring layer comprises:
a first insulating layer formed at the one surface of the substrate, to cover the contact pad exposed through the chip accommodating portion;
a first electrode pattern layer formed on the first insulating layer, to electrically interconnect the contact pad and the conductive via;
a second insulating layer formed on the first insulating layer, to cover the first electrode pattern layer;
a second electrode pattern layer formed on the second insulating layer, to provide a ground;
a third insulating layer formed on the second insulating layer, to cover the second electrode pattern layer; and
a third electrode pattern layer formed on the third insulating layer, the third electrode pattern layer comprising an antenna.

7. A manufacturing method of a semiconductor package comprising:
a substrate machining step of forming at least one through hole at a substrate made of a photosensitive glass material such that the through hole extends through one surface and the other surface of the substrate, and forming, at the substrate, a denaturation region where a chip accommodating portion will be formed;
a transmission path forming step of forming a conductive layer at the through hole, thereby forming a conductive via, forming a contact pad in the denaturation region, and forming a wiring layer for transmission of an electrical signal at the one surface of the substrate;
an etching step of removing the denaturation region in a direction from the other surface to the one surface of the substrate, thereby forming the chip accommodating portion; and
a mounting step of inserting a semiconductor chip into the chip accommodating portion, thereby connecting the semiconductor chip to the contact pad exposed through the chip accommodating portion.

8. The manufacturing method according to claim 7, further comprising:
a molding step of forming a mold such that the mold is filled between the chip accommodating portion and the semiconductor chip and covers the other surface of the substrate and the semiconductor chip; and
an additional pad forming step of removing at least a portion of the mold, thereby not only forming an input/output pad connected to the conductive via while extending through the mold, but also forming a heat dissipation pad contacting an inactive surface of the semiconductor chip while extending through the mold.

9. The manufacturing method according to claim 7, wherein the transmission path forming step comprises:
a via forming step of forming the conductive layer at the through hole, thereby forming the conductive via;
a contact pad forming step of forming the contact pad in the denaturation region; and
a multilayer forming step of stacking a plurality of insulating layers and a plurality of electrode pattern layers at the one surface of the substrate, for transmission of an electrical signal.

10. The manufacturing method according to claim 9, wherein:
the substrate machining step comprises:
a through hole forming step of forming at least one through hole extending through the one surface and the other surface of the substrate;
a groove forming step of forming at least one contact pad groove having a shape concave from the one surface of the substrate toward the other surface of the substrate at a portion of the substrate where the denaturation region will be formed; and
a denaturation step of denaturing a portion of the substrate where the semiconductor chip will be mounted, thereby forming the denaturation region;
the contact pad forming step comprises filling the contact pad groove formed in the denaturation region with a conductive material, thereby forming the contact pad; and
the etching step comprises etching the denaturation region from the other surface toward the one surface of the substrate, and stopping the etching when the contact pad is exposed, thereby forming a residual portion having a predetermined thickness from the one surface of the substrate toward the other surface of the substrate.

11. The manufacturing method according to claim 10, wherein the multilayer forming step comprises directly forming a second insulating layer at the one surface of the substrate such that the second insulating layer covers the contact pad, and
sequentially forming a second electrode pattern layer, a third insulating layer and a third electrode pattern layer.

12. The manufacturing method according to claim 10, further comprising:
a protruded bump forming step between the via forming step and the contact pad forming step,
wherein the protruded bump forming step comprises exposing the contact pad groove, forming a mask such that the mask covers the one surface of the substrate, sequentially forming a seed layer, a solder and an under-bump metal along an inner wall of the contact pad groove, thereby forming a concave portion at a central portion of the under-bump meta, and removing the mask,
wherein the contact pad forming step comprises filling the concave portion of the under-bump metal, thereby forming a contact pad having a protrusion protruding in a direction toward the other surface of the substrate,
wherein the etching step comprises etching the denaturation region from the other surface of the substrate toward the one surface of the substrate, and stopping the etching when the contact pad is exposed after exposure of the seed layer, thereby forming a residual portion having a predetermined thickness from the one surface of the substrate toward the other surface of the substrate, and
wherein the manufacturing method further comprises, between the etching step and the mounting step, a reflow step of removing the seed layer, and performing reflow of the solder, thereby forming a first bump.
